(19) United States
(12) Patent Application Publication
(10) Pub. No.: US 2017/0271131 A1
(43) Pub. Date: Sep. 21, 2017

(54) ORIENTED LASER ACTIVATED PROCESSING CHAMBER

(71) Applicant: Applied Materials, Inc., Santa Clara, CA (US)

(72) Inventors: Stephen MOFFATT, St. Brelade (JE); Joseph M. RANISH, San Jose, CA (US)

(21) Appl. No.: 15/456,943

(22) Filed: Mar. 13, 2017

Related U.S. Application Data
(60) Provisional application No. 62/309,145, filed on Mar. 16, 2016.

(51) Int. Cl. H01J 37/32; C23C 16/46; H01L 21/311; H01L 21/67

(52) U.S. Cl. CPC H01J 37/32889; H01L 21/67069; C23C 16/46; H01L 21/31116

(57) ABSTRACT

Implementations described herein provide apparatus and methods for laser-assisted deposition of films while forming electronic devices. In one implementation, a method for depositing a layer on one or more substrates is provided. The method comprises flowing a deposition precursor gas across a surface of the one or more substrates disposed within a processing volume of a processing chamber, thermally activating the deposition precursor gas to deposit a material layer on the surface of the one or more substrates, dissociating an etch precursor gas in a gas activation cell by exposing the etch precursor gas to photons from an energy source assembly having a wavelength selected for pyrolytic dissociation of the etch precursor gas and introducing the dissociated etch precursor gas into the processing volume to etch at least a portion of the material layer from the surface of the one or more substrates.

### CROSS-REFERENCE TO RELATED APPLICATIONS

This application claims benefit of U.S. provisional patent application Ser. No. 62/309,145, filed Mar. 16, 2016. The aforementioned related patent application is herein incorporated by reference in its entirety.

### BACKGROUND

Field

Implementations of the present disclosure generally relate to fabrication of integrated circuits. More particularly, the implementations described herein provide apparatus and methods for laser-assisted deposition and etching of films while forming electronic devices.

Description of the Related Art

As smaller transistors are manufactured, ultra-shallow source/drain junctions are becoming more challenging to produce. Generally, sub-100 nm CMOS (complementary metal-oxide semiconductor) devices call for a junction depth to be less than 30 nm. Selective epitaxial deposition is often utilized to form epilayers of silicon-containing materials (e.g., Si, SiGe and SiC) into the junctions. Generally, selective epitaxial deposition permits growth of epilayers on silicon moats with no growth on dielectric areas. Selective epitaxy can be used within semiconductor devices, such as elevated source/drains, source/drain extensions, contact plugs or base layer deposition of bipolar devices.

Generally, a selective epitaxy process involves a deposition reaction and an etch reaction. The deposition and etch reactions occur simultaneously with relatively different reaction rates to an epitaxial layer and to a polycrystalline layer. During the deposition process, the epitaxial layer is formed on a monocrystalline surface while a polycrystalline layer is deposited on at least a second layer, such as an existing polycrystalline layer and/or an amorphous layer. However, the deposited polycrystalline layer is generally etched at a faster rate than the epitaxial layer. Therefore, by changing the concentration of an etchant gas, the net selective process results in deposition of epitaxy material and limited, or no, deposition of polycrystalline material. For example, a selective epitaxy process may result in the formation of an epilayer of silicon-containing material on a monocrystalline silicon surface while no deposition is left on the spacer.

Selective epitaxy deposition of silicon-containing materials has become a useful technique during formation of elevated source/drain and source/drain extension features, for example, during the formation of silicon-containing MOSFET (metal oxide semiconductor field effect transistor) devices. Source/drain extension features are manufactured by etching a silicon surface to make a recessed source/drain feature and subsequently filling the etched surface with a selectively grown epilayers, such as a silicon germanium (SiGe) material. Selective epitaxy permits near complete dopant activation with in-situ doping, so that the post annealing process is omitted. Therefore, junction depth can be defined accurately by silicon etching and selective epitaxy. On the other hand, the ultra-shallow source/drain junction inevitably results in increased series resistance. In addition, junction consumption during silicide formation increases the series resistance even further. An elevated source/drain is epitaxially and selectively grown on the junction to compensate for junction consumption. Typically, the elevated source/drain layer is undoped silicon.

However, current selective epitaxy processes have some drawbacks. In order to maintain selectivity during present epitaxy processes, chemical concentrations of the precursors, as well as reaction temperatures, are regulated and adjusted throughout the deposition process. If not enough silicon precursor is administered, then the etching reaction may dominate and the overall process is slowed down. Further, harmful overetching of substrate features may occur. If not enough etchant precursor is administered, then the deposition reaction may dominate reducing the selectivity to form monocrystalline and polycrystalline materials across the substrate surface. In addition, current selective epitaxy processes usually call for a high reaction temperature, such as about 700 degrees Celsius, 1,000 degrees Celsius or higher. Such high temperatures are not desirable during a fabrication process due to thermal budget considerations and possible uncontrolled nitridation reactions to the substrate surface.

Therefore, there is a need for new methods and apparatus for fast, accurate deposition/etch processes performed at low temperatures.

### SUMMARY

Implementations of the present disclosure generally relate to fabrication of integrated circuits. More particularly, the implementations described herein provide apparatus and methods for laser-assisted deposition and etching of films while forming electronic devices.

In one implementation, a processing system is provided. The processing system comprises a processing chamber, comprising a chamber wall defining a processing volume, a substrate support for supporting one or more substrates within the processing volume, and a gas activation region formed in the processing volume. The processing system further comprises an energy source assembly positioned external to the processing chamber and for providing radiant energy to the gas activation region to dissociate the etchant gas. The energy source assembly comprises an optical cavity having a proximal end and a distal end, a first reflector positioned at the proximal end, a second reflector positioned at the distal end, the optical cavity being defined by the first reflector and the second reflector, and a gain medium disposed axially with respect to the optical cavity for providing optical gain, wherein the energy source assembly produces an axial emission of radiant energy from at least the distal end to the proximal end.

In another implementation, a processing system is provided. The processing system comprises a processing chamber, comprising a chamber wall defining a processing volume, a substrate support for supporting one or more substrates within the processing volume and a gas activation cell positioned in the processing volume. The gas activation cell comprises a housing defining a gas activation region, an inlet formed in the housing for delivering an etchant gas to the gas activation region, and an outlet formed in the housing for delivering a dissociated etchant gas from the gas activation region to the processing volume. The processing system further comprises an energy source assembly positioned external or ex-situ to the processing chamber and for providing radiant energy to the gas activation region of the gas activation cell to dissociate the etchant gas. The energy source assembly comprises an optical cavity having a proximal end and a distal end, a first reflector positioned at the proximal end, a second reflector positioned at the distal end, the optical cavity being defined by the first reflector and the second reflector and a gain medium disposed axially with respect to the optical cavity for providing optical gain. The energy source assembly produces an axial emission of radiant energy from at least the distal end to the proximal end.

In yet another implementation, a processing system is provided. The processing system comprises a processing chamber, a gas activation cell and an energy source assembly. The processing chamber comprises a substrate support for supporting one or more substrates within the processing chamber. The gas activation cell is coupled to the processing chamber. The gas activation cell comprises a housing defining a gas activation region, an inlet formed in the housing for delivering an etchant gas to the gas activation region and an outlet formed in the housing for delivering a dissociated etchant gas from the gas activation region to the processing chamber. The energy source assembly provides radiant energy to the gas activation region of the gas activation cell to dissociate the etchant gas. The energy source assembly comprises an optical cavity having a proximal end and a distal end, a first reflector positioned at the proximal end, a second reflector positioned at the distal end, the optical cavity being defined by the first reflector and the second reflector and a gain medium disposed axially with respect to the optical cavity for providing optical gain. The energy source assembly produces an axial emission of radiant energy from at least the distal end to the proximal end.

In yet another implementation, a method for depositing a layer on one or more substrates is provided. The method comprises flowing a deposition precursor gas across a surface of the one or more substrates disposed within a processing volume of a processing chamber. The method further comprises thermally activating the deposition precursor gas to deposit a material layer on the surface of the one or more substrates. The method further comprises dissociating an etch precursor gas in a gas activation cell by exposing the etch precursor gas to photons from an energy source assembly having a wavelength selected for pyrolytic dissociation of the etch precursor gas. The method further comprises introducing the dissociated etch precursor gas into the processing volume to etch at least a portion of the material layer from the surface of the one or more substrates.

### BRIEF DESCRIPTION OF THE DRAWINGS

So that the manner in which the above-recited features of the present disclosure can be understood in detail, a more particular description of the implementations, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 is a schematic view of a processing system having a gas activation cell assembly positioned external to a processing chamber in accordance with some implementations of the present disclosure;

FIG. 2 is a schematic view of another processing system having a gas activation cell assembly positioned external to a processing chamber in accordance with some implementations of the present disclosure;

FIG. 3 is a schematic view of a gas activation cell assembly in accordance with some implementations of the present disclosure;

FIG. 4 is a schematic view of another processing system having a gas activation cell assembly positioned external to a processing chamber in accordance with some implementations of the present disclosure;

FIG. 5 is a schematic view of a processing system having a processing chamber with a gas activation cell assembly positioned internal to the processing chamber in accordance with some implementations of the present disclosure; and

FIG. 6 depicts a flow chart of a method for performing a selective deposition process in accordance with some implementations of the present disclosure.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

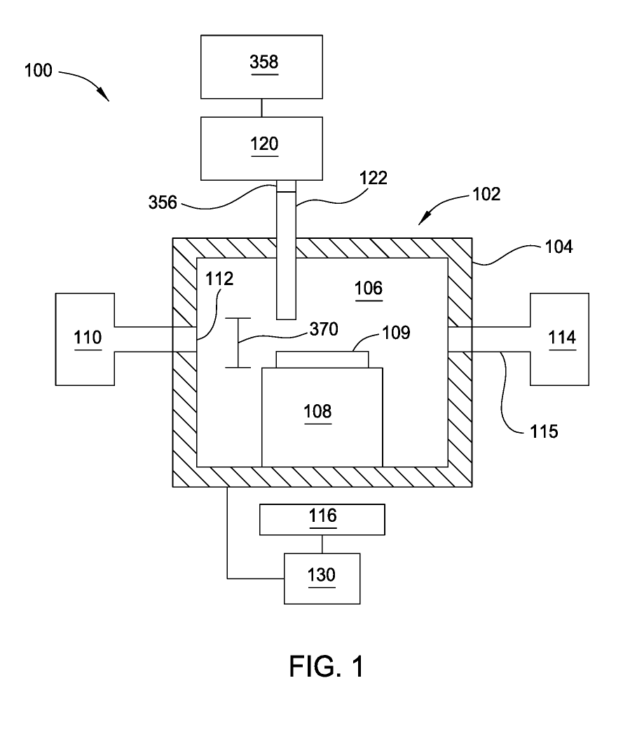

The following disclosure describes apparatus and methods for laser photo-excited etch and deposition of a layer on one or more substrates. Certain details are set forth in the following description and in FIGS. 1-6 to provide a thorough understanding of various implementations of the disclosure. Other details describing well-known structures and systems often associated with laser processing and selective deposition are not set forth in the following disclosure to avoid unnecessarily obscuring the description of the various implementations.

Many of the details, dimensions, angles and other features shown in the Figures are merely illustrative of particular implementations. Accordingly, other implementations can have other details, components, dimensions, angles and features without departing from the spirit or scope of the present disclosure. In addition, further implementations of the disclosure can be practiced without several of the details described below.

Implementations described herein will be described below in reference to a selective epitaxial deposition process that can be carried out using an epitaxial deposition system, such as a reduced pressure (“RP”) EPI chamber available from Applied Materials, Inc. of Santa Clara, Calif. Other tools capable of performing etch, deposition and combined etch/deposition processes may also be adapted to benefit from the implementations described herein. The apparatus description described herein is illustrative and should not be construed or interpreted as limiting the scope of the implementations described herein. In addition, the implementations described herein are not limited to a selective epitaxial process but are also applicable to processes where dissociation of etchant gases is desirable (e.g., cleaning processes).

Conventional selective epitaxial processes use hydrogen chloride (“HCl”) as an etchant and thermally decompose the HCl into hydrogen and chlorine. In order to achieve reasonable etch rates sufficient thermal energy greater than 700 degrees Celsius is often used. Such temperatures are not desirable during a fabrication process due to thermal budget considerations. Some implementations described herein, thermally dissociate a chlorine-containing gas (e.g., Cl₂ into Cl+Cl), which is a more efficient process at lower temperature (because dissociation is typically performed at lower energy) and is viable at lower temperatures (e.g., 450 to 650 degrees Celsius). Operating the etch processes at a lower temperature improves the speed of the etch/deposition process since the etch and deposition processes can be performed at the same or similar temperatures. The ability to perform the etch/deposition processes at the same or similar temperatures reduces the need for lengthy heating and cooling cycles of the processing chamber reducing substrate processing time and increasing overall substrate throughput.

Some implementations described herein, use an intense energy source to dissociate the etchant gas (e.g., chlorine-containing gas). In some implementations, photons from the intense energy source are recycled through a gain medium to amplify the energy source creating a circulating optical high intensity field inside an optical cavity. In some implementations, the energy source has a wavelength of about 325 nm (e.g., LED) to about 355 nm third harmonic Nd:YAG to provide a near resonant efficient process. In some implementations, the dissociated etchant gas is delivered at a distance (e.g., about 5 centimeters) from the surface of the substrate or surface of the substrate support to reduce recombination of the dissociated etchant gas.

FIG. 1 is a schematic view of a processing system 100 having a gas activation cell assembly 120 positioned external or ex-situ to a processing chamber 102 in accordance with some implementations of the present disclosure. The processing system 100 may be a semiconductor processing system. The processing system 100 includes the processing chamber 102, a gas supply 110, a controller 130, an exhaust system 114 a heating module 116, and the gas activation cell assembly 120. Although illustratively shown as coupled to an illustrative processing chamber 102 in FIG. 1, the gas activation cell assembly 120 in accordance with the present disclosure may be utilized in other suitable processing chambers as well. For example, the gas activation cell assembly 120 may be coupled to processing chambers such as those performing, e.g., epitaxial growth, reduced pressure epitaxial growth, chemical vapor deposition (CVD), an atomic layer deposition (ALD) process, an atomic layer epitaxy (ALE), or any other processing chamber using processes requiring activated gases (e.g., dissociated gases). One such exemplary chamber that may benefit from the use of a gas activation cell assembly as described herein is the RP EPI chamber available from Applied Materials, Inc. of Santa Clara, Calif. Further, although the gas activation cell is positioned external in relation to the processing chamber, the gas activation cell may be positioned within the processing chamber as will be discussed herein.

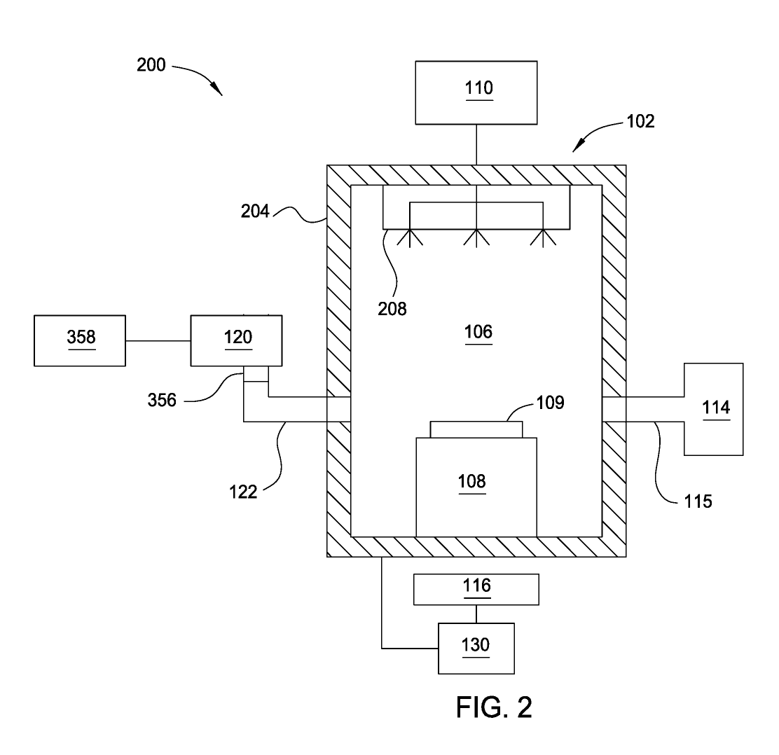

The processing chamber 102 includes a processing chamber wall 104 at least partially defining a processing volume 106. The processing chamber 102 may be a reduced pressure (“RP”) processing chamber. The processing chamber 102 may be an etching chamber. At least one substrate support pedestal 108 is disposed in the processing chamber 102 to support one or more substrates 109 thereupon during processing. The one or more substrates 109 can be brought into the processing chamber 102 through a loading port, which is obscured by the substrate support pedestal 108 in FIG. 1. The substrate support pedestal 108 may be any support pedestal for holding one or more semiconductor substrates and may include such components as an electrostatic chuck, clamps, edge rings, guide pins, or the like for physically locating and retaining the substrate. In one implementation, the substrate support pedestal 108 is configured for rotation during processing. In one implementation, the substrate support pedestal 108 includes additional components for processing the one or more substrates 109, such as an electrode for supplying DC or RF bias power, systems for the uniform supply or removal of heat from the one or more substrates 109 or a surface of the substrate support pedestal 108, or the like. Although a single substrate support pedestal 108 is shown in FIG. 1 and FIG. 2, it should be understood that multiple substrate support pedestals each for supporting one or more substrates may be positioned in the processing volume 106.

The gas supply 110 provides one or more suitable process gases for processing the substrate and/or for maintaining the processing chamber 102 (such as deposition gases, etch gases, cleaning gases, or the like). In one implementation, the gas supply 110 comprises a plurality of gas sources supplying one or more process gases to the processing chamber 102. Each process gas may be supplied independently, or in combination with additional process gases. Other components for controlling the flow of gases to the processing chamber 102, such as flow controllers, valves, or the like, are, for simplicity, not shown.

The gas supply 110 provides process gases to the processing chamber 102 in any suitable manner, such as via inlets, a showerhead, gas distribution nozzles, or the like. In one implementation, the gas supply 110 provides process gases to the processing chamber 102 via a side inlet 112. For example, some processing chambers, such as those configured for epitaxial deposition of silicon may utilize a laminar flow or a cross-flow gas distribution system wherein process gases are flowed across the surface of a substrate being processed.

In one implementation, the exhaust system 114 is coupled to the processing chamber 102 via an exhaust port 115. The exhaust system 114 may be coupled to the processing chamber 102 at any suitable location for exhausting the processing chamber 102, such as along a sidewall of the chamber, as illustrated in FIG. 1. For example, depending upon chamber design and process gas flow considerations, the exhaust port 115 may be located at any suitable location in the processing chamber 102, such as in a sidewall of the processing chamber 102, above or below the surface of the substrate support pedestal 108, in a ceiling or lid of the processing chamber, in a floor of the processing chamber, or in any other suitable location.

The heating module 116 is adapted to heat the substrate 109 during film formation within the processing chamber 102. It is contemplated that more than one heating module, and/or other heating module locations may be used. For example, the heating module 116 may be positioned relatively below and adjacent to the substrate support pedestal 108 so that the one or more substrates 109 is heated from the backside of the substrate support pedestal 108. In one implementation, the heating module 116 is positioned above the substrate support pedestal 108 to heat the surface of the one or more substrates 109. In either case, the heating module 116 may include, for example, a lamp array or any other suitable heating source and/or element. Additionally or alternatively, the substrate support pedestal 108 may be provided with a heating element (not shown) to aid in heating of the substrate. For example, the heating element may be a resistive heater embedded within the substrate support.

In one implementation, the gas activation cell assembly 120 is coupled to the processing chamber 102 via an inlet conduit 122. The gas activation cell assembly 120 may be coupled to the processing chamber 102 at any suitable location for delivering the dissociated gases to the processing volume 106, such as along a sidewall of the chamber, as illustrated in FIG. 1. For example, depending upon chamber design and process gas flow considerations, the inlet conduit 122 may be located at any suitable location in the processing chamber 102, such as in a sidewall of the processing chamber 102, above or below the surface of the substrate support pedestal 108, in a ceiling or lid of the processing chamber, in a floor of the processing chamber, or in any other suitable location.

A controller 130 is provided to facilitate control and integration of the systems of the processing system 100. The controller 130 comprises a central processing unit (CPU), a memory, and support circuits. The controller 130 is coupled with the various components of the processing system 100 to facilitate control of the gas activation cell, the gas supply, and the exhaust system.

FIG. 2 is a schematic view of another processing system 200 having the gas activation cell assembly 120 positioned external to the processing chamber 102 in accordance with some implementations of the present disclosure. Similar to the processing system 100, the processing system 200 includes the processing chamber 102, a gas supply 110, an exhaust system 114 a heating module 116, the gas activation cell assembly 120, and a controller 130. The processing system 200 further includes a showerhead 208 for delivering processing gases to the processing volume 106. The gas supply 110 provides processing gases to the processing chamber 102 via the showerhead 208. The size, geometry, number, and location of holes in the showerhead 208 can be selectively chosen to facilitate a predefined pattern of gas flow. The showerhead 208 depicted in FIG. 2 is exemplary and the gases may enter the processing chamber through other suitable mechanisms, such as nozzles, inlets, and/or fixtures in the chamber wall, proximate the substrate, or by any other suitable means for performing the intended process in the processing chamber 102. In one implementation, the showerhead 208 forms at least part of an electrode for supplying DC or RF power for the purposes of creating or maintaining a plasma from one or more of the process gases supplied by the gas supply 110.

As depicted in FIG. 2, the gas activation cell assembly 120 is coupled to the processing chamber 102 via an inlet conduit 122. The gas activation cell assembly 120 may be coupled to the processing chamber 102 at any suitable location for delivering the dissociated gases to the processing volume 106, such as along a wall 204 or sidewall of the chamber. In one implementation, the gas activation cell assembly 120 is fluidly coupled with the showerhead 208 to deliver activated gases to the processing volume 106 via the showerhead 208.

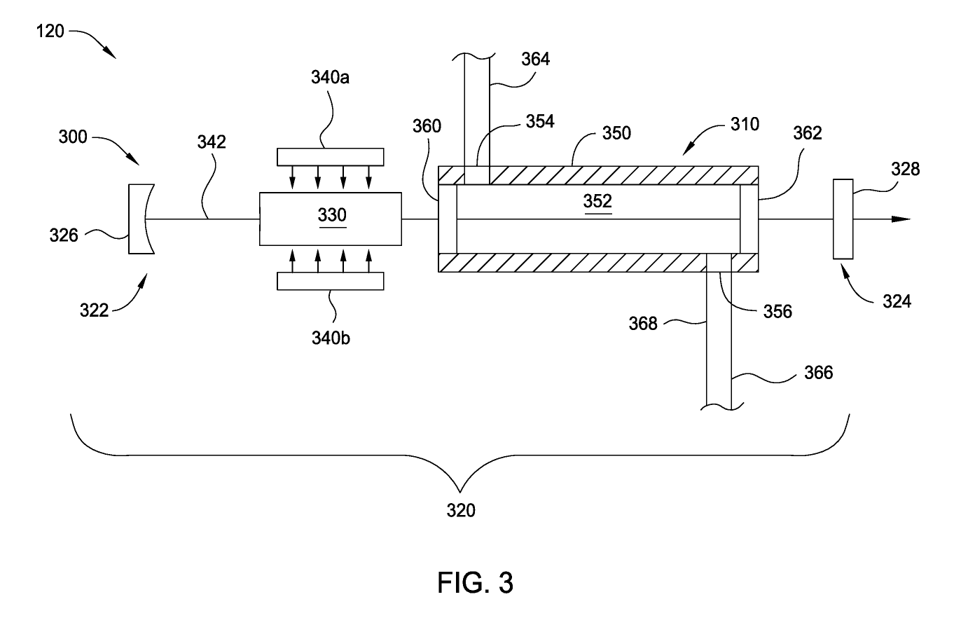

FIG. 3 is a schematic view of the gas activation cell assembly 120 in accordance with some implementations of the present disclosure. The gas activation cell assembly 120 includes an energy source assembly 300 and a gas activation cell 310. The gas activation cell assembly 120 is configured to recycle photons back through a gain medium to amplify the radiant energy produced by the energy source assembly 300. In one implementation, the radiant energy is produced by a radiation source. In one implementation, the radiation source comprises a laser source, a bright light emitting diode (LED) source, or a thermal source. The energy source assembly 300 includes an optical cavity 320 having a proximal end 322 and a distal end 324. The energy source assembly 300 further includes a first reflector 326 disposed at the proximal end 322 and a second reflector 328 disposed at the distal end 324, the optical cavity 320 being defined by the first reflector 326 and the second reflector 328. The energy source assembly 300 further includes a gain medium 330 for providing optical gain to the energy source assembly 300 and a pump source 340a, 340b (collectively 340) positioned adjacent to the gain medium 330 for providing energy to the energy source assembly 300. The gain medium 330 is disposed transversely or axially with respect to the optical cavity 320. The gas activation cell 310 is also disposed transversely or axially with respect to the optical cavity 320. The gas activation cell 310 is positioned between the gain medium 330 and the second reflector 328. The gas activation cell 310 may be at other locations between the proximal end 322 and the distal end 324 transverse or axial to the optical cavity 320. For example, the gas activation cell 310 may be positioned between the gain medium 330 and the first reflector. The energy source assembly 300 produces an axial emission of radiant energy 342 from at least the distal end 324 of the optical cavity 320 to the proximal end 322 of the optical cavity 320. In some implementations, the energy source assembly 300 forms a laser light sheet. In some implementations, the energy source assembly 300 includes at least one of multiple laser beam sources and rastered laser beam sources.

The gas activation cell 310 generally includes a housing 350 defining a gas activation region 352 or an inner volume for providing radiant energy to etchant gases present in the gas activation region 352 of the housing 350 during use. The housing 350 may be of any desirable shape, volume, or composition commensurate with holding, flowing, or activating the etchant gases. It is contemplated that the shape, volume, and composition of the housing 350 may depend on, for example, the identity of the etchant gases, the chosen residence time of etchant gases flowing through the housing 350, and the recombination rate of the dissociated etchant gas. In some implementations, the housing 350 may be absent or largely absent, with the gas activation region 352 or inner volume being mainly defined by the laser beam dimensions and region of etching gas. The housing 350 generally includes one or more inlet ports 354 for coupling with an etchant gas supply 358 and the one or more outlet ports 356 for delivering the dissociated etchant gas to the processing volume 106. In one implementation, the etchant gas supply 358 provides one or more etchant species, such as a halogen-containing species, such as a halogen-containing gas, for example, hydrochloric acid (HCl), chlorine (Cl₂), fluorine (F₂), nitrogen trifluoride (NF₃), or the like.

In one implementation, one or more interior surfaces of the housing 350 are configured to reflect radiant energy toward the gas activation region 352 of the gas activation cell 310. In one implementation, one or more interior surfaces of the housing 350 are coated with a reflective coating for reflecting the radiant energy toward the gas activation region 352 of the gas activation cell 310. The reflective material may comprise any suitable process-compatible reflective material, such as at least one of gold (Au), nickel (Ni), silver (Ag), reflective quartz, reflective dielectric materials, or the like. The reflective material is chemically resistant to the etchant gases used in the gas activation region 352.

The housing 350 includes a first transparent window 360 and a second transparent window 362 opposing the first transparent window 360 for luminescent coupling of the gas activation region 352 with the axial emission of light or radiant energy 342. The first transparent window 360 and the second transparent window 362 may comprise any suitable material, thickness, and/or geometry that facilitate illumination of the gas activation region 352 by the energy source assembly 300. The first transparent window 360 and the second transparent window 362 may be non-absorbing, or at most weakly absorbing in the wavelength range utilized by the energy source assembly 300. In one implementation, the first transparent window 360 and the second transparent window 362 comprises or consists of quartz.

The one or more inlet ports 354 may be coupled to the etchant gas supply directly, or via a conduit 364, as illustrated in FIG. 3. Although shown as being straight, the conduit 364 may be curved, angled, or otherwise configured to couple the housing 350 to the etchant gas supply. The one or more outlet ports 356 may be coupled to the processing volume 106 of the processing chamber 102 directly, or via a conduit 366, as illustrated in FIG. 3. In one implementation, the conduit 366 has at least a straight portion 368 extending into the processing volume 106 and having a length at least as long as necessary to deliver the dissociated etchant gas at a suitable distance 370 from the surface of the substrate 109 while reducing recombination of the dissociated etchant gases. For example, when the dissociated etchant gas comprises chlorine, the length of the straight portion 368 of the conduit 366 is such that the distance 370 between the end of the conduit 366 and the surface of the substrate 109 or the substrate support pedestal 108 is between about 1 cm and/or up to about 50 cm (e.g., between about 5 cm and/or up to about 10 cm). Of course, the chosen length of the straight portion 368 of the conduit 366 will depend on many factors such as upon the flow rate of the dissociated etchant gas, temperature, and/or recombination rate of the dissociated etchant gas. The conduit 366 may comprise any suitable material that does not react with process gases. In some implementations, the conduit 366 is heated.

The gain medium 330 is a factor in determining the wavelength of operations and other properties of the energy source assembly 300. The gain medium 330 may be any standard lasing medium, such as a doped yttrium aluminum garnet (YAG), sapphire (aluminum oxide), beryl, emerald, ruby, yttrium vanadate, yttrium lithium fluoride (YLF), glass, or other crystal. Dopants are usually rare earth or transition metal atoms such as erbium, neodymium, ytterbium, europium, chromium, and the like. Gas lasers, dye lasers, and diode lasers may also be configured to accept a range of input frequencies across their gain bandwidths.

The gain medium 330 is typically charged before stimulated emission can occur. Conventional lasers are charged, or pumped, using a source of photons in the absorption spectrum of the gain medium. The absorption spectrum is usually different from the emission spectrum, so conventional lasers are usually charged by a broad spectrum source, such as a flash lamp, that produces numerous photons in the absorption spectrum of the gain medium, but also produces some photons in the emission spectrum of the gain medium. The absorbed photons charge the laser, and the emission photons stimulate emission of photons from the charged atoms and ions of the gain medium, setting off the cascade that produces a pulse of laser light.

The pump source 340 provides energy to the energy source assembly 300. The pump source 340 produces a pump beam incident on the gain medium 330. Examples of suitable pump sources include electrical discharges, flashlamps, arc lamps, a UV light source, a light emitting diode (LED), and light from another laser. The type of pump source used principally depends on the gain medium 330. The type of pump source also determines how the energy is transmitted to the gain medium 330.

As shown in FIG. 3, the first reflector 326 and the second reflector 328 are disposed at axial ends of the gain medium 330. In the described implementation, the first reflector 326 and the second reflector 328 are full reflectors. Each of the first reflector 326 and the second reflector 328 may be a metal mirror, a dielectric mirror or a Bragg mirror. However, other types of reflectors may be utilized. Examples of mirrors or reflectors include, but are not limited to Distributed Bragg Gratings (DBG's), Photonic Band Gap (PBG) devices, refractive means such as total internal reflection from angled surfaces partial reflection from surfaces of differing refractive index (Fresnel Refraction), and metallic surface reflection. In certain implementations, it is desirable that the first reflector 326 has between 70% and 100% reflection (e.g., between 75% and 98% percent reflection) while the second reflector 328 has between 70% and 100% reflection (e.g., between 75% and 98% percent reflection). The high reflectivity of the first reflector 326 and the second reflector 328 recycles the photons back and forth between the reflectors 326 and 328 back through the gain medium 330 where the photons are amplified. The reflectors 326 and 328 may be of any desirable shape commensurate with reflecting the photons. It is contemplated that the shape, volume, and composition of the reflectors 326 and 328 may depend on the identity of the energy source and the chosen reflectivity. Exemplary shapes for the reflectors 326 and 328 include round, elliptical, piano, spherical, rectangular and cylindrical.

While reflectors 326 and 328 have been illustrated as being similar, the reflectors 326 and 328 may be substantially different from each other. In some implementations, it may be advantageous to have reflectors 326, 328 having different properties. Any further discussion of these reflectors will assume that they are similar and only the transmission characteristics of the reflectors 326, 328 are varied.

As discussed above, a certain percentage of the photons inside the optical cavity 320 will resonate between reflectors 326 and 328. Only photons that are traveling in the correct direction and oscillating at the correct mode are transmitted past reflectors 326 and 328. The reflectors 326 and 328 serve a two-fold purpose. The reflectors 326 and 328 are tuned to a particular frequency or mode so that the reflectors 326 and 328 only reflect most of the photons oscillating at that chosen frequency and second, the reflectors, by transmitting or scattering all other photons, create a resonating or amplification effect of the chosen frequency.

Photons that pass between the first reflector 326 and the second reflector 328 may interact with gas molecules, ions, and/or radicals in the gas activation region 352 of the housing 350. Interactions between a photon and a gas species may result in absorption of energy from the photon to produce an energetically excited species. In some cases, a molecule may become ionized as the photon stimulates loss of an electron. In other cases, a radical may be produced for example by photolysis. The degree of interaction between the photons and the gas may be quantified by the absorption cross-section of the gas, which is a function gas composition and quantum state, typically wavelength and polarization state, of incident light. The absorption cross-section defines the probability that a given number of photons interacting with a given number of particles will result in absorption of energy from a photon to a particle.

The optical cavity 320 greatly increases the efficiency of activation because photons typically pass through the housing 350 many times before exiting the optical cavity 320. Unactivated gas flows into the housing 350 through the conduit 364 and interacts with photons while flowing through the housing 350 to the conduit 366. As the gas interacts with photons, some species in the gas absorb energy and move to a higher energy state, potentially creating ions or radicals. Species at higher energy states typically have lower absorption cross-sections, so the absorption cross-section of the gas generally declines along the axis of the housing 350 from the inlet end at the first transparent window 360 to the outlet end at the second transparent window 362. The decline is usually not linear, since the rate of further energy absorption declines in conjunction with the absorption cross-section, but the decline may be approximately linear if the system does not approach an equilibrium state. If the system approaches an equilibrium state, the energy absorption may approach zero asymptotically.

In one implementation, the optical cavity 320 produces a beam emitted in an axial direction and having modulated threshold emission intensity at a wavelength of radiant energy in free space of between about 300 nm to about 400 nm to inject electrons and holes into the gain medium 330, which produce an optical material gain.

The radiant energy may be generated in two directions, axially along the path of the optical cavity 320. Depending on the reflectiveness of the first reflector 326 and the second reflector 328, radiant energy will either be reflected back into the optical cavity 320 or escape the optical cavity 320 and propagate down a waveguide. The energy source assembly 300 can be configured so that photons will propagate in one direction. Alternatively, it can be configured so that the photons may simultaneously propagate in both directions, i.e., through the first reflector 326 and the second reflector 328.

In one implementation, the energy source assembly includes additional components (e.g., collimating lenses) for expanding the axial emission of radiant energy 342 to enlarge the activation cross-section within the gas activation region 352 of the gas activation cell 310.

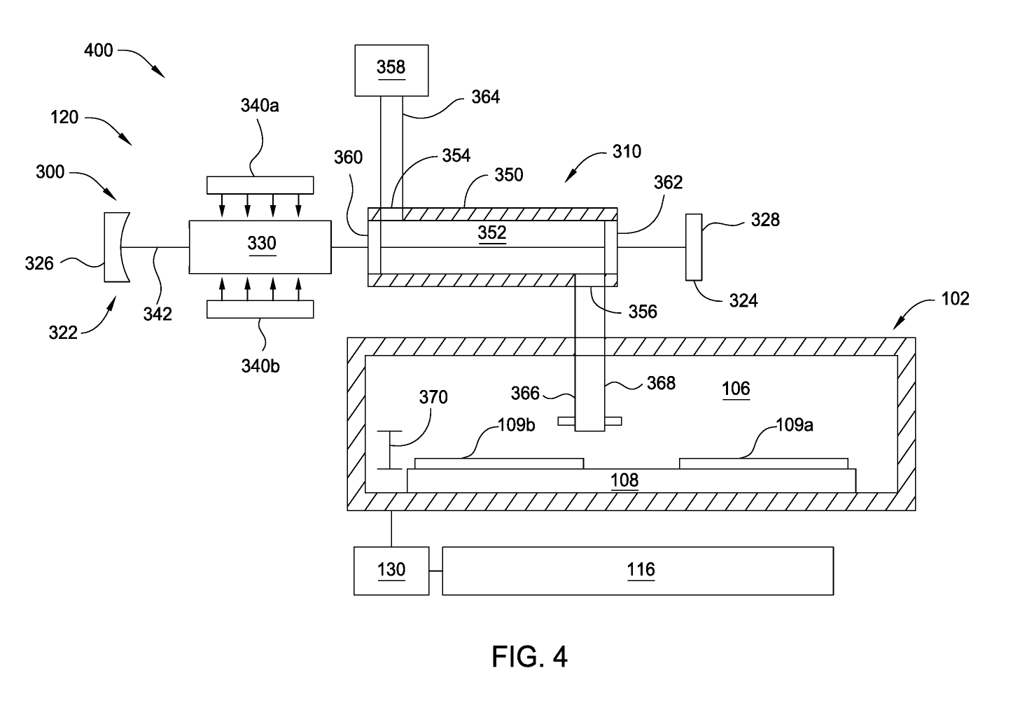

FIG. 4 is a schematic view of another processing system 400 having a gas activation cell assembly 120 positioned externally in accordance with some implementations of the present disclosure. The processing system 400 may be a semiconductor processing system. The gas activation cell assembly 120 is coupled to the processing chamber 102 via the conduit 366, which is disposed through a lid or upper wall of the processing chamber 102. The one or more inlet ports 354 may be coupled to the etchant gas supply directly, or via a conduit 364, as illustrated in FIG. 4. Although shown as being straight, the conduit 364 may be curved, angled, or otherwise configured to couple the housing 350 to the etchant gas supply. The one or more outlet ports 356 may be coupled to the processing volume 106 of the processing chamber 102 directly, or via a conduit 366, as illustrated in FIG. 4. In some implementations, the conduit 366 may have at least a straight portion 368 extending into the processing volume 106 and having a length at least as long as necessary to deliver the dissociated etchant gas at a suitable distance 370 from the surface of the one or more substrates 109 while reducing recombination of the dissociated etchant gases. For example, when the dissociated etchant gas comprises chlorine, the length of the straight portion 368 of the conduit 366 is such that the distance 370 between the end of the conduit 366 and the surface of the one or more substrates 109a, 109b (collectively 109) or the substrate support pedestal 108 is between about 1 cm and/or up to about 50 cm (e.g., between about 5 cm and/or up to about 10 cm). Of course, the chosen length of the straight portion 368 of the conduit 366 will depend on many factors such as upon the flow rate of the dissociated etchant gas, temperature, and/or recombination rate of the dissociated etchant gas. The conduit 366 may comprise any suitable material that does not react with process gases. In some implementations, the conduit 366 is heated.

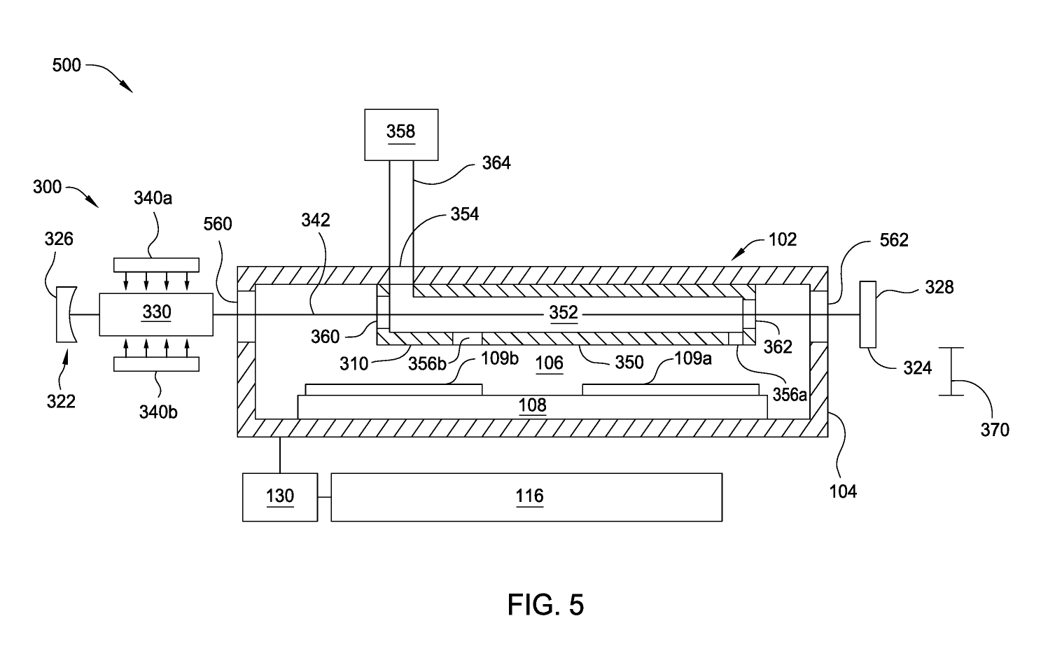

FIG. 5 is a schematic view of a processing system 500 having a processing chamber 102 with the gas activation cell assembly 120 positioned internal or in-situ to the processing chamber 102 in accordance with some implementations of the present disclosure. The processing system 500 may be a semiconductor processing system. The processing system 500 is similar to the processing system 400 except that the gas activation cell 310 is positioned within in the processing volume 106 of the processing chamber 102. In some implementations, the gas activation cell 310 is coupled with the chamber wall 104 (e.g., the ceiling). In some implementations, the gas activation cell 310 includes a showerhead arrangement. For example, in the showerhead arrangement, there are multiple inlet ports 354 and/or multiple outlet ports 356 in the housing 310. In some implementations, a portion of the housing 350 of the gas activation cell 310 is defined by the chamber wall 104.

In some implementations, the housing 350 may be absent or largely absent, with the gas activation region being mainly defined by the laser beam dimensions and region of etching gas. In some implementations where housing 350 is not present, the gas activation region 352 or inner volume may be defined by a gas curtain, for example, an inert gas curtain. In some implementations where housing 350 is not present, the gas activation region 352 may be defined by positioning of the one or more outlet ports 356.

The energy source assembly 300 is positioned external to the processing chamber 102 to protect the components of the energy source assembly (e.g., the first reflector 326, the second reflector 328, the gain medium 330, and the pump source 340) from exposure to the processing gases and processing conditions (e.g., temperatures). Positioning the gas activation cell 310 within the processing volume 106 also reduces the distance 370 from the one or more outlet ports 356 of the housing 350 and the surface of the substrate support pedestal 108 or the surface of the one or more substrates 109 (if present) while reducing recombination of the dissociated etchant gases. Although not shown, a conduit similar to the conduit 366 shown in FIG. 4 may be coupled with the one or more outlet ports 356a, 356b (collectively 356) for delivering dissociated etchant gases to the substrate. In one implementation, the distance 370 is between about 1 cm and/or up to about 50 cm (e.g., between about 5 cm and/or up to about 10 cm). In other implementations, the distance 370 may range from a fractional mean free path to tens of mean free paths.

The processing chamber 102 includes a first transparent window 560 and a second transparent window 562 opposing the first transparent window 560 for luminescent coupling of the processing volume 106 with the axial emission of radiant energy 342. The first transparent window 560 and the second transparent window 562 may comprise any suitable material, thickness, and/or geometry that facilitate illumination of the processing volume 106 by the energy source assembly 300. The first transparent window 560 and the second transparent window 562 may be non-absorbing, or at most weakly absorbing in the wavelength range utilized by the energy source assembly 300. In one implementation, the first transparent window 560 and the second transparent window 562 comprise or consist of quartz. In one implementation, the first transparent window 560 and the second transparent window 562 comprise or consist of the same materials as the first transparent window 360 and the second transparent window 362 of the gas activation cell 310.

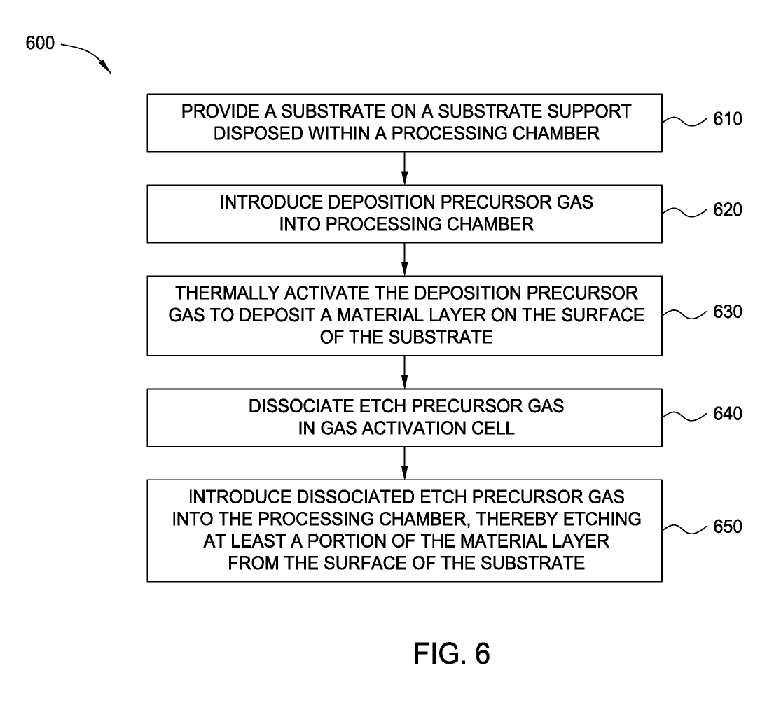

FIG. 6 depicts a flow chart of a process 600 for performing a selective deposition process in accordance with some implementations of the present disclosure. The process 600 may be used to selectively and epitaxially deposit a silicon-containing or germanium-containing compound layer on a substrate through at least an etch-deposition cyclical process. The process 600 may be equally applicable to formation of other material layers or material compounds by any processing chamber, such as a chemical vapor deposition (CVD) chamber, an atomic layer deposition (ALD) chamber, an atomic layer epitaxy (ALE) chamber, or a physical vapor deposition (PVD) chamber where etch-deposition cyclical process may be needed. The process 600 may be performed by any of the processing chambers depicted in FIGS. 1-5. Exemplary material layers or material compounds may include, but are not limited to a doped or undoped semiconductor material or compound that is selected from a group consisting of silicon, germanium, SiₓGe₁₋ₓ alloys, group III-V or group II-VI semiconductor compounds, binary compounds from Groups II-VI or Groups III-V, ternary compounds from Groups II-VI or Groups III-V, quaternary compounds from Groups II-VI or Groups III-V, or mixtures or combinations thereof.

The process 600 begins at operation 610 by providing a substrate on a substrate support disposed within a processing chamber, for example the processing chamber 102. The substrate may be subjected to a pre-clean process to remove native oxide or other unwanted contamination prior to entering the processing chamber. For example, the substrate may be exposed to a remote plasma containing fluorine at a temperature below about 100 degrees Celsius to form a sublimation layer from a native oxide layer on the substrate, and then the temperature of the substrate may be elevated above about 100 degrees Celsius to remove the sublimation layer. The substrate may also, or alternately, be exposed to HF in solution, vapor, or plasma to remove oxides from the substrate.

In general, the term “substrate” as used herein refers to objects that can be formed from any material that has some natural electrical conducting ability or a material that can be modified to provide the ability to conduct electricity. A “substrate surface,” as used herein, refers to any substrate surface upon which a material or energy process may be performed. It is contemplated that a substrate surface may contain features such as transistor junctions, via, contact, line, or any other interconnect facet, e.g., vertical or horizontal interconnect. In one implementation, the substrate surface may include more than one material, such as exposed monocrystalline silicon surface areas and features that are covered with dielectric material, such as oxide or nitride layers.

The processing chamber may be tailored to a predetermined temperature and pressure that are suitable for a process to be performed on the substrate surface. In various implementations of the present disclosure, the processing chamber may be maintained at a consistent temperature throughout the etch-deposition cyclical process. As discussed herein, with the aid of photon energy from a pump source to promote dissociation of the etchant gases in the gas activation cell, the processing chamber may be switched rapidly between an etch mode and a deposition mode without increasing the temperature during the etching process. The thermal budget is therefore reduced without sacrificing growth rate of the material layer. In one example, the processing chamber may be maintained at a consistent temperature less than about 700 degrees Celsius, such as between about 250 degrees Celsius and about 650 degrees Celsius, for example between about 300 degrees Celsius and about 600 degrees Celsius. The appropriate temperature depends on the particular precursor(s) used to deposit and/or etch the material layer. The processing chamber may be maintained at a pressure from about 0.01 Torr to about 100 Torr, for example from about 0.1 Torr to about 20 Torr, or from about 1 Torr to about 10 Torr.

At operation 620, a deposition precursor gas is introduced into the processing chamber. The deposition precursor gas may be a gaseous precursor. The deposition precursor gas may be introduced as a gas mixture of one or more deposition precursor gases. In one implementation where a silicon-containing compound layer is chosen, the deposition precursor gas may contain a silicon source (e.g., one or more silanes with the empirical formula SiₓH₍₂ₓ₊₂₎, wherein x=1, 2, 3, 4, etc.). In one implementation where a doped silicon-containing compound layer, for example a doped silicon germanium carbon (SiGeC) is chosen, the deposition precursor gas may contain a silicon source (e.g., silane), a carrier gas (e.g., N₂), a germanium source (e.g., GeH₄), and a carbon source (e.g., SiH₃CH₃). The deposition precursor gas may further contain a dopant compound (e.g., PH₃) to provide a source of a dopant.

At operation 630, the deposition precursor gas is thermally activated to deposit a material layer on the surface of the substrate. The molecules in the deposition precursor gas is thermally activated at an appropriate temperature using the thermal energy from a heat source (e.g., the substrate support pedestal 108 of FIGS. 1-5) to react and epitaxially deposit a doped silicon-containing compound layer, for example a doped SiGeC compound on the substrate surface. For a substrate surface including exposed monocrystalline silicon surface areas and features that are covered with dielectric material, the epitaxial layer of doped SiGeC compound is formed on the monocrystalline surface of the substrate while an amorphous or polycrystalline layer of doped SiGeC compound is formed on features of the substrate that are covered with dielectric material. The deposition precursor gas may be thermally activated at a temperature from about 400 degrees Celsius to about 700 degrees Celsius (e.g. from about 250 degrees Celsius and about 650 degrees Celsius; from about 500 degrees Celsius to about 600 degrees Celsius.) For example, silane may be thermally decomposed at about 500 degrees Celsius.

At operation 640, the etch precursor gas is dissociated in a gas activation cell. The etch precursor gas may contain an etchant (e.g., Cl₂ or HCl). The etch precursor gas is delivered to a gas activation cell such as gas activation cell 310 where the etch precursor gas is exposed to photon energy from a radiation source to dissociate the etch precursor gas. As discussed herein, the gas activation cell may be positioned external to the processing chamber or may be positioned internal within the processing volume of the processing chamber.

Chlorine may enhance selective epitaxial growth process. Therefore in some cases where HCl is used as etch precursor gas, chlorine or chlorine-based gas may be additionally flowed into the gas activation cell to enhance the selective epitaxial growth process. In the implementation as described here, by exposing the substrate to reactive CI species the reactive CI species will react with the growing film to form volatile SiCl₄ and GeCl₄ species that etch the film. In practice, the etch rate of the film that is deposited on the surrounding materials is much faster than the etch rate of the film that is growing epitaxially on the exposed monocrystalline silicon. These two mechanisms combine to yield a chosen epitaxial film on the exposed monocrystalline silicon and little or no film on the surrounding materials.

The photon energy of the radiation source may be below the minimum necessary for photodissociation of the etch precursor gas (in the absence of heat). However, the radiation source should be bright enough to provide an abundance of photons with sufficient power and intensity (i.e., photons are energetic enough to break the bonds in the precursor gas) that would significantly decrease the absorption length of precursors when present in a large volume, for example via multiphoton absorption. In other words, even though the radiation energy is delivered at a wavelength off the peak wavelengths for dissociation of the etch precursor gas such as chlorine (180 nm-200 nm), or in some situations the photon energy of the radiation source may not sufficiently enough to photodissociate whole volume of molecules in the etch precursor gas within the gas activation cell, a bright radiation source would still be able to provide a number of photons that may be 5 or 10 times more than necessary for effective photodissociation of whole volume of molecules in the precursor gas. One useful radiation source, for a process at any given pressure of, for example about 0.1 Torr to about 100 Torr, may be a UV fiber laser emitted at 355 nm wavelength and power density between about 0.1 mJ/cm² and about 0.7 mJ/cm². Such a UV fiber laser (or other radiation source with the light characteristics as discussed previously) is believed to be able to photolytically dissociate most of the precursor gases that are commonly used in an epitaxy process.

The radiation source may be any type of laser as discussed above with respect to FIGS. 1-5. In one implementation, the radiation source is a bundle of fiber lasers operating in the wavelength range of about 190 nm and about 420 nm, for example about 355 nm or 365 nm. To effect the etching reaction, the electromagnetic radiation may be delivered at an average intensity between about 0.1 mJ/cm² and about 1.0 J/cm², such as 0.5 mJ/cm² in short pulses of duration between about 1 nanoseconds and about 100 nanoseconds, such as between about 5 nanoseconds and about 50 nanoseconds, for example about 10 nanoseconds. A plurality of such pulses may be applied to the etch precursor gas, with a duration between the pulses between about 500 nanoseconds and about 1 millisecond, such as between about 1 microsecond and about 500 microseconds, for example about 100 microseconds.

At operation 650, the dissociated etch precursor gas is introduced into the processing volume of the processing chamber, thus etching at least a portion of the material layer from the surface of the substrate. The dissociated etch precursor gas may be delivered at about 5 centimeters to about 24 centimeters from the surface of the substrate. The substrate may be heated using the same thermal energy at the same temperature from the deposition process of operation 630.

A cycle of the deposition process as discussed in operation 620, operation 630, operation 640, and operation 650 may be repeated as needed until a chosen thickness of a doped silicon-containing compound layer, for example the doped SiGeC compound, is formed on the substrate surface.

In some implementations, the deposition precursor gas and dissociated etch precursor gas may be introduced into the processing volume of the processing chamber concurrently into the processing chamber through different gas inlets to prevent premature or undesired reaction of the precursor gases prior to entering the processing chamber.

In summary, some of the benefits of the present disclosure include the efficient integration of a gas activation cell for dissociating etchant gases at low temperatures into currently available processing systems. Currently, etchant gases are heated at temperatures greater than 700 degrees Celsius to dissociate the etchant gas. Heating the etchant gases typically involves an increase in temperature relative to the deposition process, which adversely affects thermal budget considerations. Further, current processes suffer from recombination of the dissociated etchant gases thus reducing the amount of dissociated etchant available for the etching process. It has been found by the inventors that using an intense energy source, which is recycled through a gain medium to amplify the energy source, to dissociate the etchant gas produces an increased amount of dissociated etchant gases at lower temperatures relative to currently known processes. In addition, the dissociated etchant gases can be delivered at a distance relatively close to the substrate surface being etched to reduce the amount of recombination.

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the disclosure may be devised without departing from the basic scope thereof, and the scope thereof is determined by the claims that follow.

1. A processing system, comprising:
a processing chamber, comprising:
a chamber wall defining a processing volume;
a substrate support for supporting one or more substrates within the processing volume; and
a gas activation region formed in the processing volume; and
an energy source assembly positioned external to the processing chamber and for providing radiant energy to the gas activation region to dissociate the etchant gas, the energy source assembly comprising:
an optical cavity having a proximal end and a distal end;
a first reflector positioned at the proximal end;
a second reflector positioned at the distal end, the optical cavity being defined by the first reflector and the second reflector; and
a gain medium disposed axially with respect to the optical cavity for providing optical gain, wherein the energy source assembly produces an axial emission of radiant energy from at least the distal end to the proximal end.

2. The processing system of claim 1, wherein the gas activation region is located axially with respect to the optical cavity.

3. The processing system of claim 2, wherein the gas activation region is located between the gain medium and the second reflector.

4. The processing system of claim 1, wherein the gas activation region is defined by a housing and the housing includes a first transparent window and a second transparent window for luminescent coupling of the gas activation region with the axial emission of radiant energy.

5. The processing system of claim 1, wherein the gain medium is selected from the group consisting of: a doped yttrium aluminum garnet (YAG), sapphire (aluminum oxide), beryl, emerald, ruby, yttrium vanadate, yttrium lithium fluoride (YLF), or glass.

6. The processing system of claim 1, further comprising a pump source positioned adjacent to the gain medium for providing radiant energy to the gain medium.

7. The processing system of claim 1, wherein the first reflector and the second reflector are positioned to reflect radiant energy back into the optical cavity and through the gain medium.

8. The processing system of claim 7, wherein the first reflector has between 75% and 98% percent reflection while the second reflector has between 75% and 98% percent reflection.

9. The processing system of claim 1, wherein the processing chamber includes a first transparent window and a second transparent window opposing the first transparent window for luminescent coupling of the processing volume with the axial emission of radiant energy.

10. A processing system, comprising:
a processing chamber, comprising:
a substrate support for supporting one or more substrates within the processing chamber; and
a gas activation cell coupled to the processing chamber, comprising:
a housing defining a gas activation region;
an inlet formed in the housing for delivering an etchant gas to the gas activation region; and
an outlet formed in the housing for delivering a dissociated etchant gas from the gas activation region to the processing chamber; and
an energy source assembly for providing radiant energy to the gas activation region of the gas activation cell to dissociate the etchant gas, the energy source assembly comprising:
an optical cavity having a proximal end and a distal end;
a first reflector positioned at the proximal end;
a second reflector positioned at the distal end, the optical cavity being defined by the first reflector and the second reflector; and
a gain medium disposed axially with respect to the optical cavity for providing optical gain, wherein the energy source assembly produces an axial emission of radiant energy from at least the distal end to the proximal end.

11. The processing system of claim 10, wherein the gas activation cell is disposed axially with respect to the optical cavity.

12. The processing system of claim 11, wherein the gas activation cell is positioned between the gain medium and the second reflector.

13. The processing system of claim 10, wherein the housing includes a first transparent window and a second transparent window for luminescent coupling of the gas activation region with the axial emission of radiant energy.

14. The processing system of claim 10, wherein the outlet is coupled to the processing chamber via a conduit having a straight portion extending into the processing chamber.

15. The processing system of claim 14, wherein the conduit is heated.

16. A method for depositing a layer on one or more substrates, comprising:
flowing a deposition precursor gas across a surface of one or more substrates disposed within a processing volume of a processing chamber;
thermally activating the deposition precursor gas to deposit a material layer on the surface of the one or more substrates;
dissociating an etch precursor gas in a gas activation cell by exposing the etch precursor gas to photons from an energy source assembly having a wavelength selected for pyrolytic dissociation of the etch precursor gas; and
introducing the dissociated etch precursor gas into the processing volume to etch at least a portion of the material layer from the surface of the one or more substrates.

17. The method of claim 16, wherein the gas activation cell is positioned in the processing volume of the processing chamber.

18. The method of claim 16, wherein the gas activation cell is positioned external to the processing chamber.

19. The method of claim 16, wherein the processing chamber is maintained at a temperature between about 250 degrees Celsius and about 650 degrees Celsius while thermally activating the deposition precursor gas to deposit a material layer on the surface of the one or more substrates and etching at least a portion of the material layer from the surface of the one or more substrates.

20. The method of claim 19, wherein the processing chamber is maintained at a pressure from about 0.1 Torr to about 20 Torr while thermally activating the deposition precursor gas to deposit a material layer on the surface of the substrate and etching at least a portion of the material layer from the surface of the one or more substrates.
